(19) United States
(12) Patent Application Publication
(10) Pub. No.: US 2026/0275792 A1
(43) Pub. Date: Sep. 17, 2026

(54) APPARATUS AND METHOD FOR TESTING AUTOMATIC DOOR MOTOR

(71) Applicant: GM GLOBAL TECHNOLOGY OPERATIONS LLC, Detroit, MI (US)

(72) Inventors: Eric Michael MARGGRANDER, China, MI (US); Robert J. KOPITZKI, Lake Orion, MI (US); Erik Richard RASMUSSEN, Garden City, MI (US)

(21) Appl. No.: 19/076,247

(22) Filed: Mar. 11, 2025

(51) Int. Cl. E05F 7/00; E05F 15/611

(52) U.S. Cl. CPC E05F 7/00; E05F 15/611; E05Y 2201/41; E05Y 2900/531; E05Y 2999/00

(57) ABSTRACT

An apparatus configured to test a motor configured to close a door, the apparatus including: a piston within a cylinder; a spring mounted within the cylinder in cooperation with the piston, the spring movable between a compressed configuration and an expanded configuration to move the piston; and a trigger assembly mounted to the cylinder. When unlocked, the trigger assembly releases the spring to move from the compressed configuration to the expanded configuration and push the piston outward from the retracted position to the extended position. The spring is configured to push the piston with a predetermined amount of force expected to activate the motor to pivot the door and bring a door latch into contact with a door striker.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to an apparatus and method for testing a motor of an automatic door.

Automatic doors include a motor, which is configured to open and close the door, or at least assist a user when opening and closing the door. The motor may be configured to move the door from an open position to a closed position in response to the door being lightly pushed by a user. To open the door, a button or lever is typically actuated to unlatch the door. The motor will then activate to open the door further in response to the door being lightly pushed by a user.

### SUMMARY

The present disclosure provides for, in various features, an apparatus configured to test a motor configured to close a door. The apparatus includes: a cylinder; a piston seated within the cylinder and extending out from within the cylinder, the piston movable between a retracted position and an extended position; a spring mounted within the cylinder in cooperation with the piston, the spring movable between a compressed configuration and an expanded configuration to move the piston from the retracted position to the extended position; and a trigger assembly mounted to the cylinder and movable between a locked position and an unlocked position, in the locked position the trigger assembly is configured to cooperate with the piston to hold the piston in the retracted position and maintain the spring in the compressed configuration, and in the unlocked position the trigger assembly is not in cooperation with the piston thereby freeing the spring to move from the compressed configuration to the expanded configuration and push the piston outward from the retracted position to the extended position. The spring is configured to push the piston outward from the retracted position to the extended position with a predetermined amount of force expected to activate the motor to pivot the door and bring a door latch into contact with a door striker.

In further features, the spring is a compression spring.

In further features, the trigger assembly includes a pin movable into, and out of, cooperation with the piston; and in the locked position of the trigger assembly the pin cooperates with the piston to retain the piston in the retracted position, and in the unlocked position the pin is decoupled from the piston to permit the piston to move from the retracted position to the extended position.

In further features, the trigger assembly further includes a lever in cooperation with the pin to move the pin such that actuation of the lever moves the pin out of cooperation with the piston.

In further features, the predetermined amount of force is sufficient to activate the motor to pivot the door and bring the door latch into contact with the door striker only when the motor has a predetermined friction torque or less than a predetermined friction torque.

In further features, the predetermined amount of force is expected to overcome friction of the motor to activate the motor to pivot the door and bring the door latch into contact with the door striker.

In further features, the predetermined amount of force is 80 Nm.

In further features, the predetermined amount of force is 90 Nm.

In further features, the spring is configured to apply the predetermined amount of force against the door with the door open to a predetermined open distance between the door latch and the door striker, the predetermined open distance equal to an overall length of the apparatus with the piston in the retracted position.

In further features, a biasing member is configured to return the trigger assembly to the locked position after being moved to the unlocked position.

The present disclosure also provides for, in various features, an apparatus configured to test a motor of a door, the apparatus including: a cylinder; a piston rod seated within the cylinder and extending out from within the cylinder, the piston rod movable between a retracted position and an extended position; a compression spring mounted within the cylinder in cooperation with the piston rod, the compression spring movable between a compressed configuration and an expanded configuration to move the piston rod from the retracted position to the extended position; and a trigger assembly mounted to the cylinder and movable between a locked position and an unlocked position by a lever in cooperation with a pin, in the locked position the pin is in cooperation with the piston rod to hold the piston rod in the retracted position and maintain the compression spring in the compressed configuration, and in the unlocked position the pin is decoupled from the piston rod thereby freeing the compression spring to move from the compressed configuration to the expanded configuration and push the piston rod outward from the retracted position to the extended position. The compression spring is configured to push the piston rod outward from the retracted position to the extended position with a predetermined amount of force expected to activate the motor and overcome friction of the motor to cause the motor to pivot the door a distance sufficient to bring a door latch into contact with a door striker.

In further features, the predetermined amount of force is sufficient to activate the motor to pivot the door and bring the door latch of the door into contact with the door striker only when the motor has a predetermined friction torque or less than a predetermined friction torque.

In further features, the predetermined amount of force is 80 Nm.

In further features, the predetermined amount of force is 90 Nm.

The present disclosure still further provides for, in various features, a method for testing a motor configured to close a door. The method includes the following: setting a testing apparatus in a locked position in which a piston rod of the testing apparatus is in a retracted position within a cylinder, a trigger assembly is in cooperation with the piston rod to retain the testing apparatus in the locked position, and a spring within the cylinder in cooperation with the piston rod is in a compressed configuration storing a predetermined amount of force expected to activate the motor to pivot the door to bring a door latch into contact with a door striker; opening the door to a distance equal to a maximum overall length of the testing apparatus with the piston rod in the retracted position as measured between the door latch of the door and the door striker; positioning the testing apparatus between an operator and the door with a distal end of the piston rod in contact with an exterior of the door at a height generally aligned with the door latch of the door and the door striker; actuating the trigger assembly to decouple the trigger assembly from the piston rod, thereby freeing the spring to move from the compressed configuration to an expanded position and push the piston rod outward from the retracted position against the door at the predetermined amount of force to activate the motor and pivot the door; determining the motor to be acceptable if in response to the predetermined amount of force the motor pivots the door to bring the door latch into contact with the door striker; and determining the motor to be unacceptable if in response to the predetermined amount of force the motor fails to pivot the door a pivot distance required to bring the door latch into contact with the door striker.

In further features, the predetermined amount of force is expected to overcome friction of the motor to activate the motor to pivot the door and bring the door latch into contact with the door striker.

In further features, the motor is a first motor with a first friction torque, the method further comprising replacing the first motor with a second motor having a second friction torque that is lower than the first friction torque after the first motor is deemed to be unacceptable.

In further features, the predetermined amount of force is sufficient to activate the motor to pivot the door and bring the door latch into contact with the door striker only when the motor satisfies a predetermined friction torque requirement.

In further features, the predetermined amount of force is 80 Nm.

In further features, actuating the trigger assembly includes depressing a lever mounted to the cylinder to unlock the trigger assembly from cooperation with the piston rod, a biasing member is configured to return the lever to the locked position after depressing the lever.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of a testing apparatus of the present disclosure configured to test a motor’s ability to close a door, a piston rod of the testing apparatus is illustrated in an extended position;

FIG. 2 is a perspective view of the testing apparatus with the piston rod in a retracted position;

FIG. 3 is a cross-sectional view taken along line 3-3 of FIG. 2;

FIG. 4 illustrates the testing apparatus positioned against a door to be tested, the testing apparatus configured with the piston rod in the retracted position; and

FIG. 5 illustrates the testing apparatus subsequent to a trigger assembly thereof being activated to release the piston rod into the door to close the door.

In the drawings, reference numbers may be reused to identify similar and/or identical elements.

### DETAILED DESCRIPTION

The present disclosure is generally directed to a testing apparatus configured to test a motor of an automatic door. The motor may be configured to close any suitable door, such as a door of an automobile. The motor may be configured to close any suitable non-automotive door as well. The testing apparatus of the present disclosure is configured to test the motor of any suitable automotive door or non-automotive door. Although the present disclosure focuses on the motor as configured to close a door, the motor may be configured to open a door as well. The motor provides an assist to the user to facilitate closing a door (and optionally opening a door), such as a relatively large door of a sport utility vehicle (SUV).

The motor is configured to move the door from an open position to a closed position in response to the door being lightly pushed by a user. For example, upon lightly nudging the door, the motor will activate and rotate the door inward until a latch of the door comes into contact with a striker at a door frame in a cinching position. The striker, the latch, and a locking mechanism will then cooperate to draw the door inward to a locked position to perform a soft close of the door.

For the motor to be acceptable, it must typically be configured to pivot the door and bring the door latch into contact with the door striker in response to a predetermined amount of force applied to the door by the user when the user pushes the door. The predetermined amount of force is set based on what is deemed to be an acceptable amount of force for the user to use. The predetermined amount of force may be set by an original equipment manufacturer, for example.

The testing apparatus of the present disclosure is configured to apply the predetermined amount of force to the door to test whether the motor of the door is acceptable. With the door open as described below, the testing apparatus can be used to apply the predetermined amount of force to the door. If in response to receiving the predetermined amount of force the motor activates and pivots the door far enough for the door latch to engage the striker, then the motor is determined to be acceptable. But, if in response to the predetermined amount of force the motor fails to rotate the door far enough for the door latch to cooperate with the striker, then the motor will be determined to be unacceptable. The motor may be unacceptable for a variety of different reasons, for example, the motor may have too much friction. The excess friction may be a result of, for example, the windings receiving too much current, the magnets being too strong, etc.

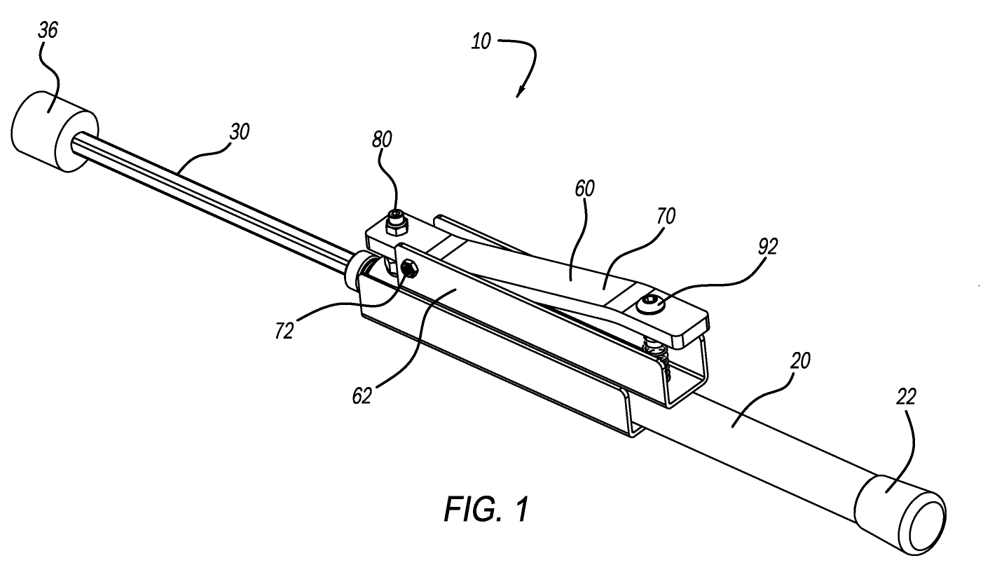

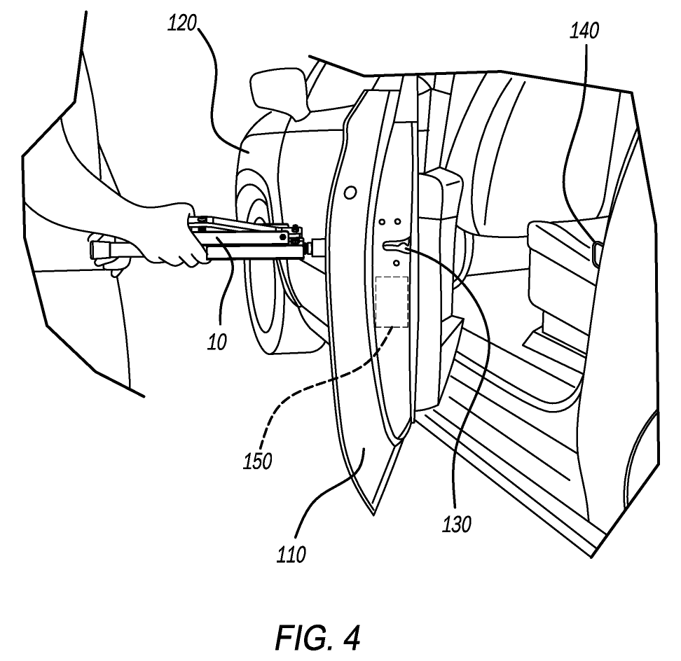

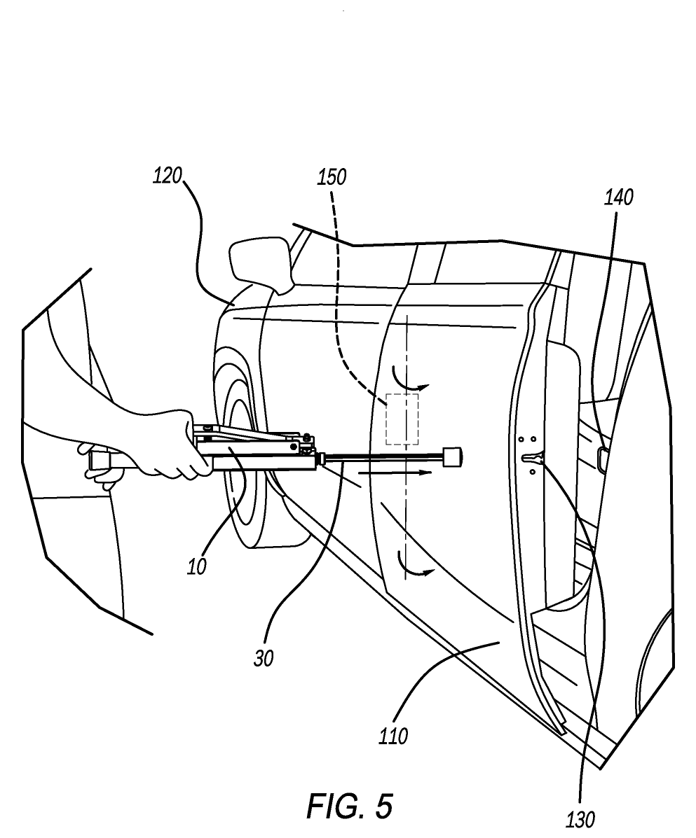

FIGS. 1-3 illustrate an example of a testing apparatus 10 in accordance with the present disclosure configured to test a motor configured to close (and optionally open) a door. The door may be an automotive door (see FIGS. 4 and 5, for example), or any suitable non-automotive door. With respect to automotive doors, the door may be that of a sport utility vehicle (SUV), for example. The testing apparatus 10 is configured to apply a predetermined amount of force to the door to determine whether, in response to the predetermined amount of force, the motor is able to pivot the door far enough to bring a door latch into contact with a door striker. If in response to the predetermined amount of force the motor fails to swing the door far enough to bring the door latch into contact with the door striker, then the motor will be deemed unsuitable.

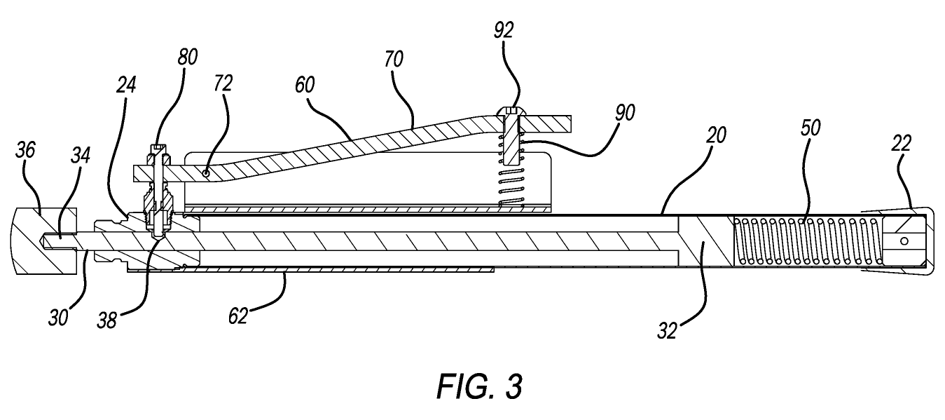

The testing apparatus 10 generally includes a cylinder 20 and a piston rod 30 slidably seated within the cylinder 20. A first end of the cylinder 20 is closed with an end cap 22. A plug 24 is at a second end of the cylinder 20, which is opposite to the first end and the end cap 22. The plug 24 defines an opening through which the piston rod 30 extends. With particular reference to FIG. 3, a proximal end 32 of the piston rod 30 remains within the cylinder 20. A distal end 34 of the piston rod 30 is outside of the cylinder 20 and is covered with a bumper 36.

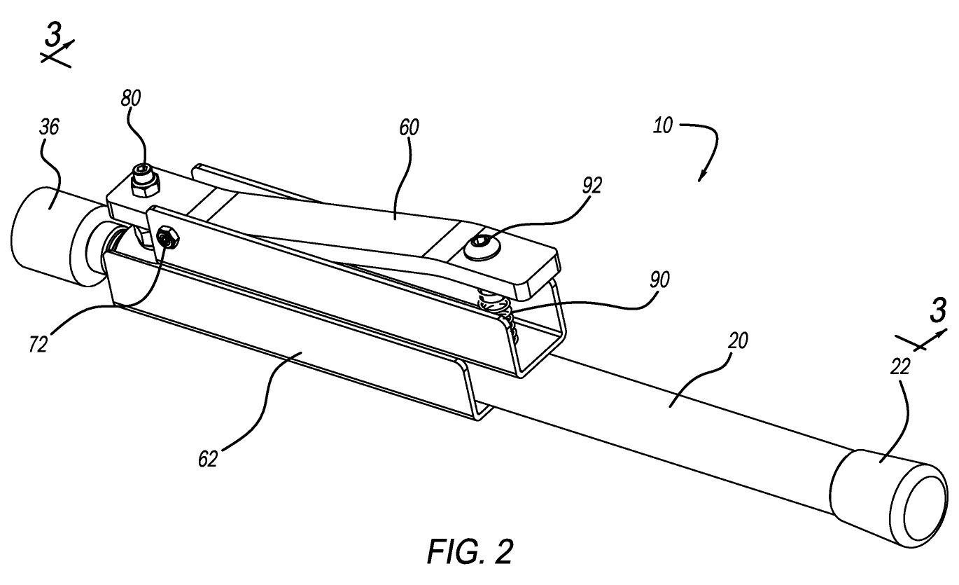

Seated within the cylinder 20 is a spring 50. The spring 50 is in cooperation with the piston rod 30 and the cylinder 20, such as at the end cap 22. The spring 50 may be any suitable biasing member, such as a compression spring. The spring 50 is movable between a compressed configuration (FIG. 3) and an expanded configuration to move the piston rod 30 from a retracted position (FIGS. 2 and 3) to an extended position (FIG. 1).

The spring 50 is configured to store, in the compressed configuration, a predetermined amount of force expected to activate a motor to pivot a door and bring a door latch into contact with a door striker. The spring 50 is thus configured to move the piston rod 30 from the retracted position to the extended position with the predetermined amount of force. The predetermined amount of force is set based on what is deemed to be an acceptable amount of force for the user to use to push the door closed. The predetermined amount of force may be, for example, 80 Nm, 90 Nm, or any other suitable amount of force. The predetermined amount of force may be set by an original equipment manufacturer, for example. Any suitable transducer or suitable force gauge may be used to measure the amount of force exerted by the piston rod 30 to confirm that the predetermined amount of force is being exerted. If the predetermined amount of force is not being exerted, the testing apparatus 10 may be modified in any suitable manner. For example, the spring 50 may be replaced with a stronger or weaker spring as appropriate.

The testing apparatus 10 further includes a trigger assembly 60. The trigger assembly 60 is mounted to the cylinder 20 in any suitable manner. In the example illustrated, the trigger assembly 60 is mounted to the cylinder 20 by way of a bracket 62. The trigger assembly 60 includes a lever 70, which may alternatively take the form of any suitable actuator, such as a button, trigger, etc. The lever 70 is mounted to the bracket 62 in any suitable manner to be pivotable about a pivot point 72. The lever 70 is in cooperation with a pin 80. The pin 80 is movable between a locked position and an unlocked position. In the locked position, the pin 80 is in cooperation with the piston rod 30, such as by way of a recess 38 defined by the piston rod 30. In the unlocked position, the pin 80 is disengaged from cooperation with the piston rod 30 to allow the spring 50 move the piston rod 30 from the retracted position (FIGS. 2 and 3) to the extended position (FIG. 1) with the predetermined amount of force.

The lever 70 is pivotable about the pivot point 72 to move the pin 80 from the locked position to the unlocked position. Specifically, when the lever 70 is pressed, the lever 70 pivots about the pivot point 72 to pull the pin 80 upward and out of cooperation with the piston rod 30, thereby allowing the spring 50 to expand and move the piston rod 30 from the retracted position to the extended position with the predetermined amount of force. Between the bracket 62 and the lever 70 is a biasing member 90, which is mounted to the lever 70 with a fastener 92. After the lever 70 is released, the biasing member 90 pushes the lever 70 upward, which presses the pin 80 back downward against the piston rod 30. When the piston rod 30 is pushed back into the cylinder 20 to the retracted position, the pin 80 will again engage the recess 38 to lock the piston rod 30 into the retracted position.

With continued reference to FIGS. 1-3, and additional reference to FIGS. 4 and 5, an exemplary method for using the testing apparatus 10 to test a motor configured to close a door will now be described. FIGS. 4 and 5 illustrate a door 110 of an exemplary vehicle 120, and a motor 150 configured to close the door 110 (and optionally open the door 110 as well). The door 110 includes a latch 130 configured to cooperate with a striker 140 mounted to a door frame. The door 110 is an exemplary door; the present disclosure applies to any suitable automotive or non-automotive door configured to be automatically closed using any suitable motor.

In response to the door 110 being lightly pressed by a user when the door 110 is open, the motor 150 is configured to activate and pull the door 110 inward until the latch 130 cooperates with the striker 140. The motor 150 may be any suitable motor configured to provide a powered assist to close the door 110. For example, the motor 150 may cooperate with a linear actuator connected to the door 110 to move the linear actuator to rotate the door to bring the latch 130 into cooperation with the striker 140. The motor 150 may be further configured to completely close the door, or the door 110 may include any suitable soft-close mechanism to completely close the door 110 after the motor 150 brings the latch 130 into cooperation with the striker 140. In some instances, the motor 150 may be unable to move the door 110 to bring the latch 130 into cooperation with the striker 140 in response to the predetermined amount of force being applied to the door. For example, the motor 150 may have too much friction. The friction may be a result of, for example, the windings receiving too much current, the magnets being too strong, etc.

The testing apparatus 10 is configured to test the motor 150 to determine whether it is capable of rotating the door 110 far enough to bring the latch 130 into cooperation with the striker 140 when the predetermined amount of force is applied to the door 110. To test the motor 150 (or any other suitable motor), the testing apparatus 10 is set with the piston rod 30 in the retracted position (FIGS. 2, 3, and 4) with the spring 50 compressed. To set the piston rod 30 in the retracted position and compress the spring 50, the piston rod 30 is pushed inward until the pin 80 engages the recess 38. The door 110 is then opened to a distance equal to a maximum overall length of the testing apparatus 10 with the piston rod 30 in the retracted position as measured between the latch 130 and the striker 140. The distance that the door 110 is open may be any suitable distance, and the same distance is maintained throughout testing for consistency.

The testing apparatus 10 is next positioned between an operator (such as on the operator’s hip, for example) and the door 110 so that the bumper 36 is in contact with an exterior surface of the door 110 at a height generally aligned with the latch 130 of the door 110 and the striker 140, as illustrated in FIG. 4. With reference to FIG. 5, the user then actuates the lever 70 to draw the pin 80 out of cooperation with the piston rod 30 to decouple the trigger assembly 60 from the piston rod 30. As a result, the spring 50 is free to move from the compressed configuration to the expanded position and push the piston rod 30 outward from the retracted position against the door 110 at the predetermined amount of force, which activates the motor 150 to pivot the door 110 inward.

If in response to being moved by the predetermined amount of force exerted by the testing apparatus 10 the motor 150 pivots the door 110 to bring the latch 130 into contact with the striker 140, the motor 150 will be determined to be acceptable. But, if in response to being moved by the predetermined amount of force exerted by the testing apparatus 10 the motor 150 fails to pivot the door 110 far enough to bring the latch 130 into contact with the striker 140, the motor 150 will be determined to be unacceptable. An unacceptable motor may be replaced with a replacement motor having a friction torque that is lower than the friction torque of the unacceptable motor. The predetermined amount of force will be sufficient to activate the motor 150 to pivot the door 110 far enough to bring the latch 130 into contact with the striker 140 only when the motor 150 exhibits friction torque that is equal to, or less than, a predetermined friction torque requirement, which may be set by an original equipment manufacturer, for example. The testing apparatus 10 is thus configured to test the friction torque of the motor 150. The testing apparatus 10 is suitable for use at any stage of production and assembly, or post-production and post-assembly. For example, the testing apparatus 10 is suitable for use at end-of-line testing at a production plant, service facility, test lab, etc. to determine whether the motor is suitable for its intended use (e.g., to determine whether the motor has a suitable friction torque).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

What is claimed is:

1. An apparatus configured to test a motor configured to close a door, the apparatus comprising:
a cylinder;
a piston seated within the cylinder and extending out from within the cylinder, the piston movable between a retracted position and an extended position;
a spring mounted within the cylinder in cooperation with the piston, the spring movable between a compressed configuration and an expanded configuration to move the piston from the retracted position to the extended position; and
a trigger assembly mounted to the cylinder and movable between a locked position and an unlocked position, in the locked position the trigger assembly is configured to cooperate with the piston to hold the piston in the retracted position and maintain the spring in the compressed configuration, and in the unlocked position the trigger assembly is not in cooperation with the piston thereby freeing the spring to move from the compressed configuration to the expanded configuration and push the piston outward from the retracted position to the extended position,
wherein the spring is configured to push the piston outward from the retracted position to the extended position with a predetermined amount of force expected to activate the motor to pivot the door and bring a door latch into contact with a door striker.

2. The apparatus of claim 1, wherein the spring is a compression spring.

3. The apparatus of claim 1, wherein:
the trigger assembly includes a pin movable into, and out of, cooperation with the piston; and
in the locked position of the trigger assembly the pin cooperates with the piston to retain the piston in the retracted position, and in the unlocked position the pin is decoupled from the piston to permit the piston to move from the retracted position to the extended position.

4. The apparatus of claim 3, wherein the trigger assembly further includes a lever in cooperation with the pin to move the pin such that actuation of the lever moves the pin out of cooperation with the piston.

5. The apparatus of claim 1, wherein the predetermined amount of force is sufficient to activate the motor to pivot the door and bring the door latch into contact with the door striker only when the motor has a predetermined friction torque or less than a predetermined friction torque.

6. The apparatus of claim 1, wherein the predetermined amount of force is expected to overcome friction of the motor to activate the motor to pivot the door and bring the door latch into contact with the door striker.

7. The apparatus of claim 1, wherein the predetermined amount of force is 80 Nm.

8. The apparatus of claim 1, wherein the predetermined amount of force is 90 Nm.

9. The apparatus of claim 1, wherein the spring is configured to apply the predetermined amount of force against the door with the door open to a predetermined open distance between the door latch and the door striker, the predetermined open distance equal to an overall length of the apparatus with the piston in the retracted position.

10. The apparatus of claim 1, further comprising a biasing member configured to return the trigger assembly to the locked position after being moved to the unlocked position.

11. An apparatus configured to test a motor of a door, the apparatus comprising:
a cylinder;
a piston rod seated within the cylinder and extending out from within the cylinder, the piston rod movable between a retracted position and an extended position;
a compression spring mounted within the cylinder in cooperation with the piston rod, the compression spring movable between a compressed configuration and an expanded configuration to move the piston rod from the retracted position to the extended position; and
a trigger assembly mounted to the cylinder and movable between a locked position and an unlocked position by a lever in cooperation with a pin, in the locked position the pin is in cooperation with the piston rod to hold the piston rod in the retracted position and maintain the compression spring in the compressed configuration, and in the unlocked position the pin is decoupled from the piston rod thereby freeing the compression spring to move from the compressed configuration to the expanded configuration and push the piston rod outward from the retracted position to the extended position,
wherein the compression spring is configured to push the piston rod outward from the retracted position to the extended position with a predetermined amount of force expected to activate the motor and overcome friction of the motor to cause the motor to pivot the door a distance sufficient to bring a door latch into contact with a door striker.

12. The apparatus of claim 11, wherein the predetermined amount of force is sufficient to activate the motor to pivot the door and bring the door latch of the door into contact with the door striker only when the motor has a predetermined friction torque or less than a predetermined friction torque.

13. The apparatus of claim 11, wherein the predetermined amount of force is 80 Nm.

14. The apparatus of claim 11, wherein the predetermined amount of force is 90 Nm.

15. A method for testing a motor configured to close a door, the method comprising:
setting a testing apparatus in a locked position in which a piston rod of the testing apparatus is in a retracted position within a cylinder, a trigger assembly is in cooperation with the piston rod to retain the testing apparatus in the locked position, and a spring within the cylinder in cooperation with the piston rod is in a compressed configuration storing a predetermined amount of force expected to activate the motor to pivot the door to bring a door latch into contact with a door striker;
opening the door to a distance equal to a maximum overall length of the testing apparatus with the piston rod in the retracted position as measured between the door latch of the door and the door striker;
positioning the testing apparatus between an operator and the door with a distal end of the piston rod in contact with an exterior of the door at a height generally aligned with the door latch of the door and the door striker;
actuating the trigger assembly to decouple the trigger assembly from the piston rod, thereby freeing the spring to move from the compressed configuration to an expanded position and push the piston rod outward from the retracted position against the door at the predetermined amount of force to activate the motor and pivot the door;
determining the motor to be acceptable if in response to the predetermined amount of force the motor pivots the door to bring the door latch into contact with the door striker; and
determining the motor to be unacceptable if in response to the predetermined amount of force the motor fails to pivot the door a pivot distance required to bring the door latch into contact with the door striker.

16. The method of claim 15, wherein the predetermined amount of force is expected to overcome friction of the motor to activate the motor to pivot the door and bring the door latch into contact with the door striker.

17. The method of claim 16, wherein the motor is a first motor with a first friction torque, the method further comprising replacing the first motor with a second motor having a second friction torque that is lower than the first friction torque after the first motor is deemed to be unacceptable.

18. The method of claim 15, wherein the predetermined amount of force is sufficient to activate the motor to pivot the door and bring the door latch into contact with the door striker only when the motor satisfies a predetermined friction torque requirement.

19. The method of claim 15, wherein the predetermined amount of force is 80 Nm.

20. The method of claim 15, wherein actuating the trigger assembly includes depressing a lever mounted to the cylinder to unlock the trigger assembly from cooperation with the piston rod, a biasing member is configured to return the lever to the locked position after depressing the lever.
